(19) United States
(12) Patent Application Publication
(10) Pub. No.: US 2026/0244804 A1
(43) Pub. Date: Aug. 20, 2026

(54) MULTI-MODAL LARGE MODEL CONSTRUCTION AND OPERATION METHOD AND SYSTEM FOR RESERVOIR DAM SAFETY

(71) Applicants: Changjiang Spatial Information Technology Engineering Co., Ltd. (Wuhan), Wuhan (CN); Huazhong University of Science and Technology, Wuhan (CN)

(72) Inventors: Shuangping Li, Wuhan (CN); Bin Zhang, Wuhan (CN); Junxing Zheng, Wuhan (CN); Zuqiang Liu, Wuhan (CN); Lin Gao, Wuhan (CN); Huabei Liu, Wuhan (CN); Dong Wang, Wuhan (CN); Xin Zhang, Wuhan (CN); Bo Shi, Wuhan (CN); Yonghua Li, Wuhan (CN); Huawei Wang, Wuhan (CN)

(21) Appl. No.: 19/337,054

(22) Filed: Sep. 23, 2025

(30) Foreign Application Priority Data
Feb. 14, 2025 (CN) 202510162733.3

(51) Int. Cl. G06F 30/13

(52) U.S. Cl. CPC G06F 30/13

(57) ABSTRACT

A multi-modal large model construction and operation method and system for reservoir dam safety, the method includes following steps: constructing a training set: the individual samples in the training set include: as model input multi-modal data: sensor data deployed on the dam, historical hidden danger records, engineering technical documents formed during various stages of dam planning, design, construction, and operation, dam safety-related information resources, geometric and material information of the BIM model, timestamp and spatial location information; and as training labels, whether a hidden danger event occurred and the probability value of the hidden danger event occurring; training a multi-modal prediction model based on the Transformer architecture using the training set; performing real-time prediction and early warning for dam safety hazards; calculating the actual impact degree of the hidden danger event, a comprehensive risk score, warning thresholds for sensors associated with the hidden danger event, and emergency measure suggestions.

### TECHNICAL FIELD

The invention belongs to the technical field of dam safety protection, and specifically relates to a multi-modal large model construction and operation method and system for reservoir dam safety.

### BACKGROUND ART

As an important component of water conservancy projects, the safety of dams directly affects the life and property safety of residents in downstream areas and the stability of the ecological environment. Therefore, the health monitoring and safety assessment of dams have always been important topics in the global engineering and scientific research fields. With the increase in the service life of dams, frequent natural disasters, and extreme environments caused by climate change, the demand for health monitoring of dam structures is becoming more urgent. How to conduct safety monitoring in real-time and efficiently in complex and changing environments has become a key challenge.

Traditional dam safety monitoring mainly relies on manual inspections and single-modality sensors. These methods have obvious shortcomings in terms of real-time performance, accuracy, and comprehensiveness. Manual inspections are inefficient, rely on experience, and are difficult to cover all hidden dangers. Single-modality monitoring, such as strain sensors, can only obtain data on a specific aspect of the dam and cannot provide an overall health assessment. For example, strain sensors can detect abnormalities but cannot identify problems such as surface cracks. The fusion and analysis of multi-modal data is an important way to improve monitoring comprehensiveness, but the high heterogeneity of data from different sensor types makes fusion analysis difficult and often fails to effectively reveal comprehensive risks.

Existing dam monitoring systems also have limitations in intelligent analysis and decision-making capabilities. Most systems rely on fixed thresholds to trigger warnings, lack flexibility, and cannot dynamically respond to complex environmental changes. Furthermore, existing warning systems usually cannot deeply analyze the causes of hidden dangers or provide effective response suggestions, making it difficult for managers to make scientific decisions in a timely manner.

The lack of historical data and knowledge bases further limits the effectiveness of existing systems. Most existing systems rely on real-time data and lack correlation analysis with historical hidden danger records and maintenance and reinforcement data, failing to fully utilize past experience for intelligent auxiliary decision-making. Historical information during dam operation is often of great significance for predicting potential risks. The isolated analysis method of existing systems easily ignores the value of this information.

Insufficient real-time monitoring and dynamic prediction capabilities are also shortcomings of current dam monitoring technologies. Facing climate change and natural disasters, the state of the dam evolves dynamically over time. Existing static monitoring methods have difficulty identifying structural hidden dangers in a timely manner and making effective warnings.

### SUMMARY OF THE INVENTION

The purpose of the invention is to solve the deficiencies existing in the above background technology, to provide a multi-modal large model construction and operation method and system for reservoir dam safety, comprehensively enhancing the scientificity and effectiveness of dam safety monitoring.

The technical solution adopted by the invention is: a multi-modal large model construction and operation method for reservoir dam safety, including the following steps:
constructing a training set: the individual samples in the training set include: as model input multi-modal data: sensor data deployed on the dam, historical hidden danger records, engineering technical documents formed during various stages of dam planning, design, construction, and operation, dam safety-related information resources, geometric and material information of the BIM model, timestamp and spatial location information; and as training labels, whether a hidden danger event occurred and the probability value of the hidden danger event occurring;
training a multi-modal prediction model based on the Transformer architecture using the training set;
performing real-time prediction and early warning for dam safety hazards using the trained model, based on real-time collected monitoring data;
calculating the actual impact degree of the hidden danger event, a comprehensive risk score, warning thresholds for sensors associated with the hidden danger event, and emergency measure suggestions based on the probability value of whether the hidden danger event occurred output by the model.

In the above technical solutions, the data is preprocessed before being used to construct the training set: cleaning the collected raw training sample data to remove abnormal data and invalid data; labeling the data in a unified format and organizing into structured data suitable for model training; time alignment of image and vibration data is achieved through timestamps, and performing unified processing of spatial coordinates.

In the above technical solutions, the sensors deployed on the dam include, but are not limited to: physical quantity sensors, vibration sensors, visual sensor data, audio sensors, and environmental sensors.

In the above technical solutions, during the model training process, a binary cross-entropy loss function, gradient descent algorithm, and L2 regularization are used to optimize model parameters.

In the above technical solutions, before training and using the multi-modal prediction model based on the Transformer architecture, the data of each input modality is preprocessed through independent encoders, and the features of each modality are fused through the multi-head self-attention mechanism of the Transformer and then used as model input.

In the above technical solutions, the actual impact degree of the hidden danger event C_{impact} is calculated using the following formula:

$${C}_{impact} = {\sum }_{i = 1}^{n} ( {I}_{i} = {P}_{failure}^{i} )$$

where Iᵢ represents the impact degree of the i-th type of hidden danger event on the dam,

$${P}_{failure}^{i}$$

is the occurrence probability of that type of hidden danger event, and n represents the number of hidden danger event types.

In the above technical solutions, the comprehensive risk score R is calculated using the following formula:

$$R = α {P}_{failure} + β {C}_{impact}$$

where α is the weight of the hidden danger occurrence probability, representing its relative importance in risk assessment, and β is the weight of the hidden danger impact degree, representing its contribution to the comprehensive score.

In the above technical solutions, the warning threshold for sensors associated with the hidden danger event is comprehensively adjusted according to the following principles and their corresponding weights:
when the occurrence probability of any type of hidden danger is greater than its set upper limit threshold, adjusting the warning threshold of the sensor associated with that hidden danger according to the magnitude by which the probability exceeds its set upper limit threshold, to increase the sensitivity of the sensor; when the occurrence probability of any type of hidden danger is less than its set lower limit threshold, adjusting the warning threshold of the sensor associated with that hidden danger according to the magnitude by which the probability is below its set lower limit threshold, to decrease the sensitivity of the sensor;
when the input dam safety-related information resources include weather forecasts of a set type and severity, adjusting the warning threshold of the sensor associated with that weather forecast according to the weather forecast, to increase the sensitivity of the sensor;
adjusting the current warning threshold of a sensor based on the deviation between the sensor's historical warning threshold and historical hidden danger records;
adjusting the current warning threshold of a sensor based on abnormal fluctuations of the sensor.

In the above technical solutions, the process of determining emergency measure suggestions includes: when the occurrence probability of any type of hidden danger is greater than its set upper limit threshold, obtaining corresponding emergency measure suggestions for that hidden danger based on the technical standards and specifications contained in the input dam safety-related information resources and the historical maintenance and reinforcement records for the corresponding hidden danger in the engineering technical documents.

The invention further provides a multi-modal large model construction and operation system for reservoir dam safety, comprising a training set construction module, a model training module, a prediction module, and an early warning module:
the training set construction module is used to construct the training set: the individual samples in the training set include: as model input multi-modal data: sensor data deployed on the dam, historical hidden danger records, engineering technical documents formed during various stages of dam planning, design, construction, and operation, dam safety-related information resources, geometric and material information of the BIM model, timestamp and spatial location information; and as training labels, whether a hidden danger event occurred and the probability value of the hidden danger event occurring;
the model training module is used to train a multi-modal prediction model based on the Transformer architecture using the training set;
the prediction module is used to perform real-time prediction and early warning for dam safety hazards using the trained model, based on real-time collected monitoring data;
the early warning module is used to calculate the actual impact degree of the hidden danger event, a comprehensive risk score, warning thresholds for sensors associated with the hidden danger event, and emergency measure suggestions based on the probability value of whether the hidden danger event occurred output by the model.

The beneficial effects of the invention are: the invention integrates multi-modal data sources (operational state data, historical records, technical documents, BIM models, etc.), achieving comprehensive perception of the dam's state throughout its entire lifecycle. The breadth and depth of the data ensure the model can accurately predict hidden danger events; through the multi-modal prediction model based on the Transformer architecture, the multi-head self-attention mechanism is used to efficiently capture correlations between modalities, improving the accuracy of hidden danger prediction; real-time prediction and early warning capabilities ensure timely response to potential safety hazards of the dam, providing reliable technical support for dam operation management; providing actual impact degree, comprehensive risk score, and dynamic warning thresholds provides a scientific basis for emergency response.

Furthermore, the invention uses data cleaning and anomaly detection to remove invalid or interfering information, ensuring high quality of training data and robustness of the model; unified formatting and time alignment processing improve the structured degree of the data, providing stable input for model training; the alignment of time and space information ensures spatiotemporal consistency between multi-modal data, enhancing the model's ability to capture complex hidden danger patterns.

Furthermore, the multi-modal data sources of the invention cover key monitoring data during dam operation (physical quantities, vibration, vision, audio, environment), comprehensively reflecting the real-time state of the dam; different types of sensor data together provide multi-dimensional information sources, improving the reliability and comprehensiveness of the model in identifying hidden danger events; including data input from environmental sensors considers the impact of external environmental changes on dam safety, enhancing the system's adaptability.

Furthermore, the invention uses a binary cross-entropy loss function, adapted to the classification problem of hidden danger prediction, ensuring optimization of classification accuracy; using gradient descent algorithm and L2 regularization improves model training efficiency, avoids overfitting, and enhances the model's generalization ability; through the combination of optimization algorithms, the stability and predictive ability of the model in complex data scenarios are ensured.

Furthermore, the independent encoding method for each modality data in the invention preserves the feature independence between modalities, ensuring information is not lost in the early stages; the multi-head self-attention mechanism of the Transformer architecture fuses multi-modal features, effectively capturing high-order interactions between modalities, improving the accuracy of hidden danger prediction; the modular structure of the model facilitates expansion and can adapt to new data modalities or changing system requirements in the future.

Furthermore, through the calculation of the impact degree of hidden danger events, the invention quantifies the actual impact of hidden danger events, providing a basis for subsequent comprehensive risk scoring; quantitative impact degree calculation provides clear analysis basis for safety management, helping decision-makers formulate more scientific response strategies.

Furthermore, the comprehensive risk score of the invention integrates the probability of hidden danger occurrence and the impact degree, providing a more comprehensive safety evaluation indicator; the introduction of weight factors flexibly adjusts the weight of hidden danger probability and impact degree in risk assessment, adapting to the needs of different scenarios; the provided comprehensive risk score lays the foundation for warning threshold setting and emergency measure suggestions.

Furthermore, when the occurrence probability of a hidden danger event exceeds the set upper threshold, the invention automatically increases the sensitivity of related sensors to detect potential safety hazards earlier and more accurately; when the occurrence probability of a hidden danger event is lower than the lower threshold, the sensitivity of the corresponding sensors is reduced accordingly, thereby avoiding excessive sensor response and reducing unnecessary warnings. When sensors are associated with weather forecast data, the invention can adjust the warning thresholds of sensors according to weather changes, especially under extreme weather conditions, providing early warnings and enhancing the dam's risk resistance capability. Based on the deviation between the sensor's historical warning threshold and hidden danger records, as well as abnormal fluctuations of the sensor, the invention dynamically adjusts the current warning threshold to avoid misjudgments or missed judgments caused by equipment failure or historical record deviations. By adjusting sensor sensitivity in real time, the invention can more accurately reflect the actual risk situation of hidden danger events, avoid false alarms and missed alarms, and can comprehensively judge based on multi-faceted information, timely adjust the working status of equipment, thereby improving the overall safety of the dam. Combined with multi-modal data and external factors (such as weather forecasts, historical data, etc.), the warning system can adaptively adjust under changing environmental conditions, improving the emergency response capability of the dam.

Furthermore, the invention proposes a process for determining emergency measure suggestions through technical standards, engineering technical documents, and historical maintenance records. When the occurrence probability of a hidden danger event exceeds the set threshold, the system will provide standardized emergency measure suggestions for specific hidden danger types based on the dam's design standards, construction specifications, and operational requirements. This ensures that emergency measures comply with industry standards, ensuring their effectiveness and feasibility. Based on historical maintenance and reinforcement records of hidden dangers, the system can extract past experience in solving similar problems and provide specific solutions for current hidden dangers. The application of historical experience helps avoid repetitive mistakes and improves the efficiency and quality of emergency response. The invention can automatically generate emergency measures based on the occurrence probability of real-time hidden danger events and related data, reducing manual intervention and improving emergency response speed; through the combination of historical maintenance records and technical standards, the system can transform accumulated experience and technical specifications into emergency response plans, enhancing the system's intelligence level and decision support capability; timely and targeted emergency measure suggestions help improve the dam's safety protection capability, reducing losses and risks after accidents occur.

Furthermore, the invention can not only improve the intelligence level of the dam safety monitoring system but also enhance its early warning and emergency response capabilities for hidden danger events. Through dynamic adjustment of sensor warning thresholds and intelligent generation of emergency measures, it can effectively predict, assess, and handle potential risks of the dam under changing environments, thereby providing more reliable guarantees for the long-term safe operation of the dam. The application of these technical solutions can greatly reduce the probability of serious accidents at dams, improve their risk management level, and ultimately ensure dam safety and social benefits.

### BRIEF DESCRIPTION OF ACCOMPANY DRAWINGS

FIG. 1 is an overall architecture diagram of the system according to the invention;

FIG. 2 is a flowchart of multi-modal monitoring data acquisition and processing inside a dam according to the invention;

FIG. 3 is a flowchart of external resource data acquisition and processing based on web search according to the invention;

FIG. 4 is a flowchart of historical dam data retrieval based on RAG according to the invention;

FIG. 5 is a flowchart of dam hidden danger evaluation based on BIM model, mathematical and physical models and their hybrid models according to the invention;

FIG. 6 is a flowchart of dam hidden danger propagation path analysis based on knowledge graph and graph database according to the invention;

FIG. 7 is a flowchart of model fine-tuning according to the invention;

FIG. 8 is a flowchart of the dam safety comprehensive warning and response mechanism according to the invention.

### SPECIFIC EMBODIMENT OF THE INVENTION

The invention will be further described in detail hereinafter with reference to the accompanying drawings and specific embodiments to facilitate a clear understanding of the invention, but they do not limit the invention.

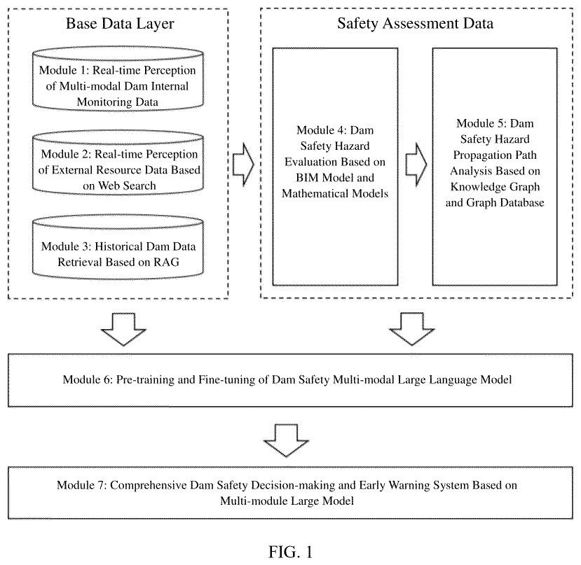

As shown in FIG. 1, the invention provides a multi-modal large model construction and operation method for reservoir dam safety, including the following steps:
constructing a training set: the individual samples in the training set include: as model input multi-modal data: sensor data deployed on the dam, historical hidden danger records, engineering technical documents formed during various stages of dam planning, design, construction, and operation, dam safety-related information resources, geometric and material information of the BIM model, timestamp and spatial location information; and as training labels, whether a hidden danger event occurred and the probability value of the hidden danger event occurring;
training a multi-modal prediction model based on the Transformer architecture using the training set;
performing real-time prediction and early warning for dam safety hazards using the trained model, based on real-time collected monitoring data;
calculating the actual impact degree of the hidden danger event, a comprehensive risk score, warning thresholds for sensors associated with the hidden danger event, and emergency measure suggestions based on the probability value of whether the hidden danger event occurred output by the model.

The principle of the invention is further explained hereinafter with reference to specific embodiments.

Embodiment 1: a multi-modal large model construction and operation system for reservoir dam safety.

As shown in FIG. 1, a multi-modal large model construction and operation system for reservoir dam safety, including the following modules:
module 1: multi-modal dam internal monitoring data real-time perception module, used for multi-modal monitoring data acquisition and processing inside the dam, obtaining real-time and historical operational state data, and generating a comprehensive real-time monitoring view of the dam's health status.

Monitoring data includes physical quantities (deformation, seepage, stress-strain, temperature, etc.), images (photos, videos, point clouds, etc.), vibration (intensity monitoring, etc.), audio (metal structure monitoring), environment (meteorology, earthquake, hydrology, etc.).

The dam health status real-time monitoring view is a comprehensive data visualization interface displaying the dam's current safety status and structural health. The dam health status real-time monitoring view displays the following data:

Real-time data overview: displays various real-time monitoring data of the dam, including physical quantities such as stress, displacement, temperature, and seepage.

Status indicators: health indicators calculated from various monitoring data, such as safety factors and risk levels, helping to quickly judge the overall health status of the dam.

Anomaly detection: displays abnormal data or warning signals detected by sensors in real time, helping managers identify potential safety hazards in a timely manner.

Visual charts: uses graphics, charts, and other forms to intuitively display data change trends, such as stress change curves and displacement distribution maps, to facilitate the identification of abnormal patterns. Regional heat maps: use heat maps to display the health status of different parts of the dam, where color depth represents different risk levels or the abnormal degree of monitoring data.

Historical comparison: provides comparison of historical monitoring data, helping to analyze changes between the current state and past states, identifying long-term trends and potential problems.

Integrating this information, the dam health status real-time monitoring view provides managers with a clear and intuitive tool to help them make quick and scientific decisions to ensure the safe operation of the dam.

Module 2: external resource data real-time perception module based on web search, used to obtain dam safety-related information resources worldwide through automated web crawler technology.

Specifically, a large amount of external resource data is obtained through web search and data scraping; inverted index and B+ tree index structures are established for the external resource data; the index and parallel query technology are used to retrieve external resource data to find target data; frequently accessed data sources and query results are cached; target data and dam operational state data are weighted and fused, and weights are dynamically adjusted according to data characteristics, forming a comprehensive information resource dataset.

Dam safety-related information resource data includes news reports worldwide on reservoir dam monitoring, safety assessment, monitoring and early warning, and maintenance and reinforcement, as well as the latest academic papers, patents, laws and regulations, and standard specifications and other technological resources. These data are combined with multi-modal sensor data to enhance the assessment capability of the dam's overall safety status. The introduction of external resource data improves the comprehensiveness of decision-making and provides rich background information and reference basis for subsequent analysis modules.

Module 3: historical data retrieval module based on RAG (Retrieval-Augmented Generation). A knowledge document library is constructed based on engineering technical documents formed during various stages of dam planning, design, construction, and operation; long documents in the knowledge document library are divided into text chunks; a text embedding model is used to convert text chunks into numerical vectors, capturing the semantic information of the text, forming a vector database; the vector database is used to retrieve text chunks related to the query, providing the most relevant information.

The dam knowledge document library covers various important data types such as survey and design data, construction records, daily dam operation data, hidden danger records, log records, hydraulic gate and turbine unit operation and maintenance records, and dam maintenance and reinforcement records, covering detailed information from all aspects of dam construction, operation, maintenance, and repair.

To ensure this information can be retrieved and utilized efficiently and accurately, Module 3 first uses embedding technology to vectorially represent historical data, converting text information into numerical vectors for subsequent calculation and comparison. This vector representation not only preserves the semantic information of the data but also improves data processing efficiency.

During the retrieval process, after the user inputs query keywords, the system first vectorizes these keywords to generate a query vector. Then, the system uses the stored vectors in the vector database to find the historical data vectors closest to the query vector through similarity calculation (such as cosine similarity). This process can quickly identify documents or records related to the user's needs.

To further improve the relevance of the retrieval results, the system subsequently uses re-ranking technology. This technology performs secondary sorting of the results based on the preliminary retrieval, optimizing the sorting order of the retrieval results by introducing more contextual information and features (such as document importance, historical retrieval frequency, etc.).

Specifically, reranking may use machine learning models to score preliminary results, comprehensively considering the relevance of the document to the query, the quality of the document, and the user's historical preferences, ensuring that users can quickly find the information that best meets their needs when querying, thereby providing strong support for subsequent risk assessment and decision-making.

This knowledge document library provides support for subsequent data analysis and also provides historical context for the system, helping to analyze current monitoring data more accurately. The historical data of the dam not only provides key references for the analysis of real-time monitoring data but also adds necessary historical background to the evaluation process, making dam safety assessment more comprehensive and accurate.

Module 4: hidden danger evaluation module based on BIM model, mathematical models, physical models, and mathematical-physical hybrid models, used to evaluate the structural strength and stability of the dam based on real-time monitoring data and historical data, obtaining hidden danger locations and types.

Mathematical models, physical models, and mathematical-physical hybrid models include finite element analysis models, fluid dynamics models, heat conduction models, and soil mechanics models.

The finite element analysis model is used to identify stress concentration areas through finite element analysis; the fluid dynamics model is used to identify areas that may suffer structural damage due to excessive water pressure or water flow scour through fluid dynamics analysis; the heat conduction model is used to identify parts where temperature changes may affect structural safety through thermal stress distribution analysis; the soil mechanics model is used to identify areas where settlement or landslides may occur through soil mechanics analysis.

Specifically, Module 4 constructs the dam's BIM model based on engineering technical documents and extracts attribute data to assign to each structural unit; associates historical operational state data, maintenance records, stress history, and other information to the corresponding parts of the BIM model; based on externally acquired information resources, incorporates the latest technical standards, specifications, laws and regulations, accident cases, and academic research into the BIM model, updating risk assessment parameters and hidden danger identification models;
it uses the geometric and material information of the BIM model to perform finite element analysis, fluid dynamics analysis, heat conduction analysis, and soil mechanics analysis, simulating the dam's response under various working conditions, identifying potential hidden danger area characteristics, including stress concentration areas, areas that may be subject to excessive water pressure or scour, areas that may develop cracks due to excessive thermal stress, and foundation areas where settlement or landslides may occur;
it compares the identified hidden danger areas with historical operational state data and historical hidden danger records in engineering technical documents to verify the accuracy of the model analysis results; it performs risk classification of the identified historical hidden dangers based on historical hidden danger characteristics;
it highlights the identified hidden danger areas in the BIM model, labeling hidden danger characteristics; continuously updates the BIM model and various analysis models as new operational data and information resources are acquired.

Module 4 achieves dynamic assessment of dam safety hazards by integrating BIM (Building Information Modeling) models, mathematical models, physical models, and hybrid models of mathematical and physical models, combined with internal monitoring data, external resource data, and historical data. The core of this module is integrating multiple models to provide comprehensive and scientific analysis results, supporting dam safety management and decision-making. By integrating these models, the system can obtain the hidden dangers and their locations in the dam.

Module 5: hidden danger propagation path analysis module based on knowledge graph and graph database, used to construct a knowledge graph and graph database, and analyze the correlation between dam structural nodes based on real-time monitoring data and historical data to identify associated hidden dangers, and achieve analysis and early warning of dam hidden danger propagation paths, obtaining associated hidden danger information and hidden danger propagation paths.

Specifically, Module 5 defines each structural unit of the dam as a structural unit node and assigns attributes; defines the physical connections and mechanical relationships between structural units as structural connection edges and assigns attributes;
it establishes association relationships between nodes and edges; establishes edges between structural unit nodes based on historical operational state data, engineering technical documents, and geometric information in the BIM model;
it stores node and edge information in a graph database; performs calculations on the nodes and edges in the graph database to obtain node connectivity and importance evaluation;
it updates the health status and risk level of nodes in the knowledge graph, as well as the weights and influence probability of edges, based on real-time collected dam operational state data and new external information resources;
it analyzes the path and probability of a hidden danger propagating from one structural unit to another using the updated node and edge attributes and the results of connectivity calculations;

Based on the hidden danger propagation probability, it constructs a matrix representing the hidden danger correlation between nodes; calculates the shortest path of hidden danger propagation from a source node to other nodes by combining the hidden danger influence matrix and the graph database; identifies nodes that have significant influence in the hidden danger propagation process based on their importance evaluation and role in the propagation process.

Since the dam structure is composed of multiple interconnected components, an abnormality in any node may trigger a chain reaction, thereby affecting the safety of the entire structure. The knowledge graph represents the various structural units of the dam and their interrelationships graphically, enabling the system to clearly display the connections and influences between nodes. The graph database, as the underlying support of the knowledge graph, can efficiently store and query complex structural information. By abstracting the dam's structural units as nodes in the graph, the attributes of each node not only include basic physical information but can also integrate multi-dimensional data such as historical hidden danger records, detection data, and maintenance records. This integration of information allows the system to quickly retrieve related nodes and analyze possible associated hidden dangers when a hidden danger occurs.

Furthermore, utilizing the powerful path calculation capability of the graph database, the system can achieve precise analysis of the hidden danger propagation path. When an abnormality occurs in a certain node, the system can quickly calculate other nodes that may be affected by this hidden danger and identify the shortest path of hidden danger propagation.

Through the combination of knowledge graph and graph database, not only can the structural correlation of the dam be systematically analyzed, but potential associated hidden dangers and their locations can be comprehensively identified, providing more reliable data support and decision-making basis for ensuring dam safety. Through this multi-level analysis method, the dam monitoring system can achieve efficient linkage from early warning to decision-making, ensuring the overall health and safety of the dam.

Module 6: multi-modal large model prediction and fine-tuning module. The multi-modal large model is pre-trained using monitoring historical data, external data, historical data, hidden danger locations and types, and hidden danger propagation paths, enabling it to learn to obtain risk assessment results, warning thresholds, and warning response mechanisms based on the real-time monitoring data, external resource data, historical dam data, hidden danger locations and types, and dam hidden danger propagation paths. The multi-modal large model is fine-tuned in combination with real-time dam monitoring data, achieving intelligent analysis and adaptive optimization of multi-modal data.

The multi-modal large language model for dam safety monitoring and evaluation is obtained after pre-training and fine-tuning the multi-modal large language model.

Specifically, during the model training process, a binary cross-entropy loss function, gradient descent algorithm, and L2 regularization are used to optimize model parameters.

Before training and using the multi-modal pre-trained model based on the Transformer architecture, the data of each input modality is preprocessed through independent encoders, and the features of each modality are fused through the multi-head self-attention mechanism of the Transformer and then used as model input.

During the training process of the multi-modal large language model, the construction of the dataset is key to the system's success. In the data preprocessing stage, data cleaning, denoising, and labeling are performed to ensure the accuracy and consistency of the input data. Through high-quality data preprocessing, the training efficiency of the model is improved, laying a solid foundation for subsequent analysis and decision support.

To improve model performance, this module uses fine-tuning technology to fine-tune the trained multi-modal large language model, making the model better adapt to dam monitoring needs.

Module 7: comprehensive decision-making and early warning module based on the multi-modal large model.

This module is used for dam safety monitoring and evaluation. It uses the pre-trained multi-modal large language model for dam safety monitoring and evaluation. By obtaining real-time monitoring data, it obtains the probability of hidden danger occurrence, the impact degree of hidden dangers, and warning thresholds, thereby outputting risk assessment results and warning response measure suggestions.
the actual impact degree of the hidden danger event C_{impact} is calculated using the following formula:

$${C}_{impact} = {\sum }_{i = 1}^{n} ( {I}_{i} = {P}_{failure}^{i} )$$

where Iᵢ represents the impact degree of the i-th type of hidden danger event on the dam,

$${P}_{failure}^{i}$$

is the occurrence probability of that type of hidden danger event, and n represents the number of hidden danger event types.
the comprehensive risk score R is calculated using the following formula:

$$R = α {P}_{failure} + β {C}_{impact}$$

where α is the weight of the hidden danger occurrence probability P_{failure} (which can be calculated by weighted summation of the occurrence probabilities of various hidden dangers), representing its relative importance in risk assessment, and β is the weight of the hidden danger impact degree, representing its contribution to the comprehensive score.

Specifically, the warning threshold for sensors associated with the hidden danger event is comprehensively adjusted according to the following principles and their corresponding weights. The setting of the weights can be based on human experience, and the final adjustment value is calculated based on the adjustment amplitude corresponding to each principle and its weight:
when the occurrence probability of any type of hidden danger is greater than its set upper limit threshold, adjusting the warning threshold of the sensor associated with that hidden danger according to the magnitude by which the probability exceeds its set upper limit threshold, to increase the sensitivity of the sensor; when the occurrence probability of any type of hidden danger is less than its set lower limit threshold, adjusting the warning threshold of the sensor associated with that hidden danger according to the magnitude by which the probability is below its set lower limit threshold, to decrease the sensitivity of the sensor;
when the input dam safety-related information resources include weather forecasts of a set type and severity, adjusting the warning threshold of the sensor associated with that weather forecast according to the weather forecast, to increase the sensitivity of the sensor;
adjusting the current warning threshold of a sensor based on the deviation between the sensor's historical warning threshold and historical hidden danger records;
adjusting the current warning threshold of a sensor based on abnormal fluctuations of the sensor.

Specifically, the process of determining emergency measure suggestions includes: when the occurrence probability of any type of hidden danger is greater than its set upper limit threshold, obtaining corresponding emergency measure suggestions for that hidden danger based on the technical standards and specifications contained in the input dam safety-related information resources and the historical maintenance and reinforcement records for the corresponding hidden danger in the engineering technical documents.

Embodiment 2: a multi-modal large model construction and operation method for reservoir dam safety implemented using the aforementioned system, including the following steps:

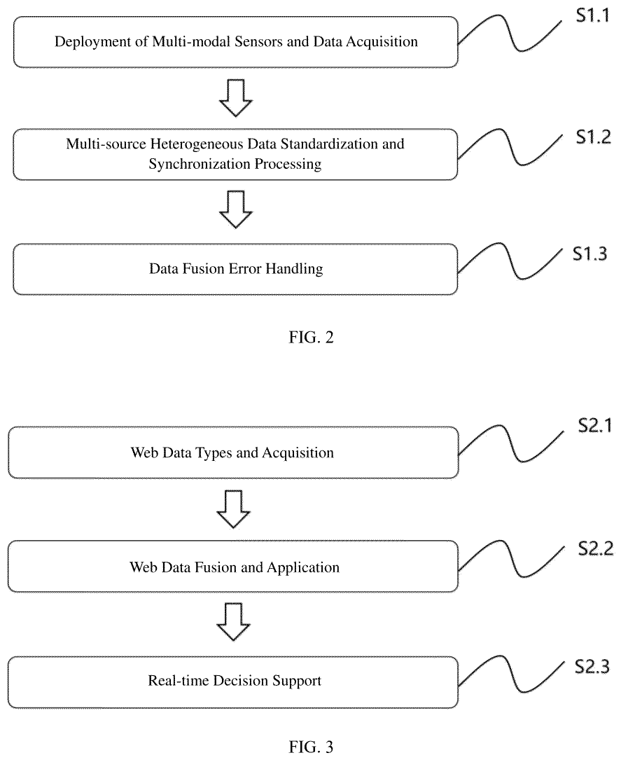

1) acquisition and processing of multi-modal sensor monitoring data inside the dam: implemented by the multi-modal dam internal monitoring data real-time perception module (Module 1). As shown in FIG. 2, the specific technical details and implementation methods are as follows:

1.1) deployment of multi-modal sensors and data acquisition.

The sensors include physical quantity sensors, vibration sensors, visual sensors, audio sensors, and environmental sensors to obtain multi-modal data. Physical quantity sensors include deformation sensors, seepage sensors, stress-strain sensors, temperature sensors, etc.; visual sensors include cameras, drones, etc.; environmental sensors include meteorological sensors, seismic sensors, hydrological sensors, etc.

The multi-modal sensors obtain real-time data, which is transmitted to the central processing system via wireless network and stored in a unified database for data processing, data fusion, and analysis by the multi-modal large model.

1.2) Multi-source heterogeneous data standardization and synchronization processing.

(1) Standardization processing can eliminate dimensional differences between data, ensuring that data from different modalities can be compared and fused under the same dimension. The data standardization formula is:

$${D}_{norm} = \frac{{D}_{i} - μ}{σ}$$

where Dᵢ is the raw data from the i-th sensor, μ is the average value of the i-th sensor's data, σ is the standard deviation of the i-th sensor's data, and Dₙₒᵣₘ is the value after standardization processing of the data from the i-th sensor. After standardization, all data are transformed into standardized data with a mean of zero and a standard deviation of one, thus ensuring relative consistency between data from different sensors.

(2) Timestamp alignment uses spatiotemporal synchronization algorithms to align the data timestamps of different sensors, ensuring that all modal data are compared and analyzed on the same time dimension. The time synchronization formula is:

$${T}_{sync} = \frac{{T}_{i 1} + {T}_{i 2} + … + {T}_{in}}{n}$$

where T_{sync} is the synchronized timestamp, Tᵢ is the timestamp of each sensor, and n is the number of sensors. This algorithm ensures consistency in the time dimension, especially for time synchronization between vibration, audio, and visual data.

1.3) Data fusion and error handling.

Data fusion from various types of sensors adopts a multi-modal weighted fusion method. The data fusion formula is:

$${D}_{fused} = {\sum }^{n} {W}_{i} {D}_{i}$$

where Dᵢ is the data from the i-th sensor, and Wᵢ is the weight of the i-th sensor's data. The system optimizes the fused data by adjusting the weight Wᵢ to more accurately reflect the actual state of the dam.

Considering the measurement accuracy of different sensors and errors that may be introduced by transmission delays, therefore, an error calculation formula is used to evaluate the precision E_{f} of data fusion:

$${E}_{f} = \sqrt{{\sum }_{i = 1}^{n}} {( {W}_{i} {D}_{i} - {D}_{fused} )}^{2}$$

This formula is used to calculate the error value generated during the fusion process of different modal data. If the data from a certain sensor produces a large error after fusion with data from other sensors, this module will dynamically adjust the data weight Wᵢ of that sensor to reduce the error and improve the overall monitoring accuracy.

2) Obtaining of external resource data related to dam safety monitoring and evaluation based on web search, implemented by the external resource data real-time perception module based on web search (Module 2), including external resource data acquisition and processing based on web search, achieved through automated web crawler technology. As shown in FIG. 3, the flowchart for external resource data acquisition and processing based on web search, specific technical details and implementation methods are as follows:

2.1) web data acquisition, including the following main steps:

(1) index establishment and retrieval: establishing an inverted index structure and adopt a B+ tree index structure. The retrieved data is sorted based on factors such as relevance and timeliness to ensure users get the most valuable information. The sorting score formula is:

$$R ( Q , P ) = α \cdot CTR + β \cdot Relevance + γ \cdot Freshness$$

where CTR is the click-through rate, Relevance is the relevance of information P to the query, Freshness is the timestamp of information publication, and α, β, γ are the weights corresponding to CTR, Relevance, and Freshness, respectively. The click-through rate (CTR) is obtained by recording the number of impressions and user clicks for each search result. When a user performs a search, the system automatically collects these data to calculate the CTR value. Relevance can be determined through manual labeling, user feedback, and machine learning models. Experts assess the relevance of each document and make adjustments based on user click behavior and satisfaction feedback. Additionally, machine learning models can automatically score by analyzing features. The acquisition of timeliness (Freshness) relies on the recorded timestamp; the system evaluates the freshness of information based on the difference between the current time and the record creation time. Through these methods, the system can comprehensively judge the quality and relevance of each search result. Through this algorithm, this module can quickly obtain and utilize the latest information related to dam safety.

(2) Data caching and updating: adopting a caching mechanism and regularly update cached data. To improve retrieval efficiency, a caching mechanism is adopted. Frequently accessed data, such as specific standards and regulations, is cached in local storage to reduce repeated queries; cached data is regularly updated to ensure data timeliness.

(3) Parallel query and distributed computing: adopting a distributed indexing scheme, distributing external data across multiple servers or nodes for processing. During queries, tasks are allocated to multiple servers for parallel processing, thereby reducing the load pressure on a single server, reducing query response time, and further improving query efficiency.

2.2) Web data fusion and application: by obtaining web data in real time, such as global patent information, international standards, laws and regulations, and the latest academic papers, the system can combine this external data with internal sensor data. Firstly, external data provides the latest technology and specification references for dam safety assessment; secondly, sensor data provides the real-time monitored health status of the dam. The system integrates these two types of data, analyzes potential risks and hidden dangers, and generates comprehensive assessment reports, thereby supporting intelligent decision-making and ensuring the safe operation and management of the dam. For example: by obtaining global patent data in real time, the system can identify the latest monitoring and reinforcement technologies, helping managers choose appropriate technical solutions for dam maintenance. By retrieving international standards and laws and regulations, the system can help dam operators adjust operational procedures to ensure compliance and reduce potential risks caused by non-compliance. The latest academic papers and research results provide managers with rich background information, helping to conduct scientific risk assessment and decision-making.

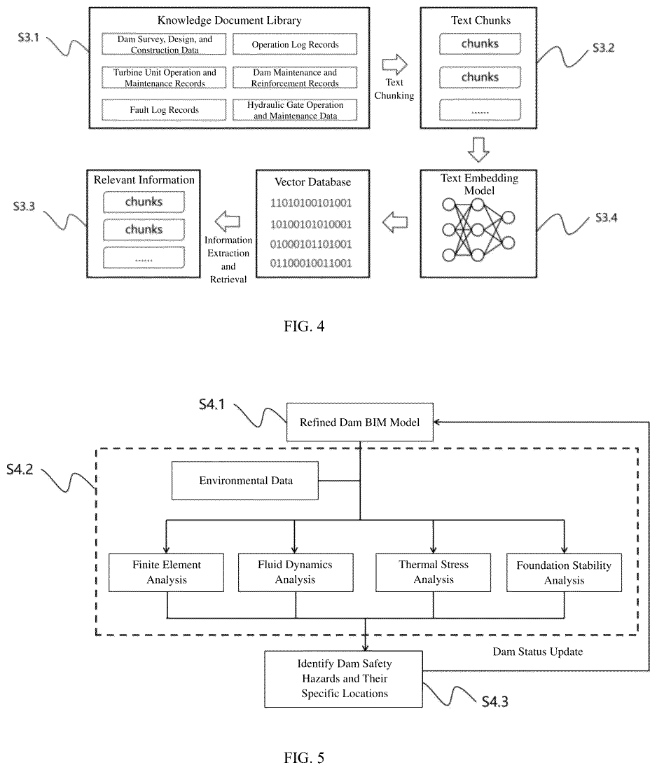

3) Obtaining historical dam data, including constructing a dam basic data knowledge base and performing efficient retrieval through a vector database, implemented by Module 3. As shown in FIG. 4, specific technical details and implementation methods are as follows:

3.1) Constructing the dam basic data knowledge base. The dam basic data knowledge base includes dam survey, design, and construction data, daily dam operation data, operation log records, fault log records, hidden danger records, turbine unit operation and maintenance records, hydraulic gate operation and maintenance data, dam maintenance and reinforcement records, etc. These documents cover detailed information from all aspects of dam construction, operation, maintenance, and repair, forming an important foundation for system analysis and decision support.

3.2) Text chunking. The documents in the dam basic data knowledge base are chunked to obtain text chunks. Text chunks represent different chapters, paragraphs, or sentences of a document. The purpose of chunking is to divide longer documents into smaller fragments to facilitate subsequent processing and calculation, improving processing speed and data operability while maintaining semantic integrity. Each text chunk contains meaningful semantic units, ensuring that subsequent information extraction steps can obtain high-quality and precise content.

3.3) Text embedding. A text embedding model is used to process the text chunks, converting the text chunks into numerical vectors to obtain text chunk vectors. All text chunk vectors together form the vector database. The semantic information of the text is represented through vectors. The finally obtained vector database is the dam basic data knowledge base.

Text embedding is achieved through machine learning algorithms. Text embedding models include Word2Vec, GloVe, and deep learning-based models like BERT. By learning contextual relationships in large-scale corpora, the model maps similar words or sentences to similar vector spaces. The closer two text chunks are semantically, the closer their distance in the vector space. Through text embedding, the system can capture subtle differences and hidden semantic information in the text, providing a foundation for information extraction and relevance analysis.

3.4) Information extraction and retrieval based on the vector database.

Information extraction and retrieval are achieved through nearest neighbor search algorithms, which can quickly find the text chunk vectors closest to the query vector and return the corresponding original text content. Nearest neighbor search algorithms include K-nearest neighbors algorithm or approximate nearest neighbor search algorithms.

In practical applications, this function can quickly find records or knowledge related to the current problem from a massive number of documents. For example, if the system needs to check the maintenance records of a specific dam, it can extract maintenance and repair data related to that dam from the dam basic data knowledge base for risk assessment or decision support.

4) Performing dynamic evaluation and analysis of dam safety hazards based on the real-time monitoring data and historical dam data, determining the type and location of hidden dangers, implemented by Module 4. As shown in FIG. 5, the specific technical details and implementation methods of the dam safety hazard evaluation process are as follows:

4.1) Construction of a refined dam BIM (Building Information Modeling) model. The BIM model uses 3D visualization to represent the dam's geometric information, material properties, construction history, and maintenance records, providing accurate basic information for the analysis of mathematical models, physical models, and mathematical-physical hybrid models.

For example, the system can use the BIM model to identify vulnerable parts of the dam or areas with historical maintenance records. These areas are often the focus of evaluation and may have potential safety hazards.

4.2) Dam safety hazard analysis integrating mathematical models, physical models, and mathematical-physical hybrid models. By combining the calculation results of the BIM model with mathematical models, physical models, and mathematical-physical hybrid models, a comprehensive safety assessment of the dam is conducted, and potential hazard areas are precisely located, determining the hazard type and location.

Mathematical models, physical models, and mathematical-physical hybrid models include finite element models, fluid dynamics models, heat conduction models, and soil mechanics models.

The BIM model provides geometric information, material properties, historical records, and foundation data for the BIM model and the calculations of mathematical models, physical models, and mathematical-physical hybrid models. The 3D geometric structure of the BIM model is composed of multiple structural units. The geometric information of each structural unit (including volume, shape, position) is discretized and passed to the finite element model, fluid dynamics model, and heat conduction model for analysis, used to improve the accuracy of simulation calculations. Material properties include the strength of concrete, elastic modulus, thermal conductivity, etc., used for mechanical analysis of the dam. Historical records include the dam's historical maintenance records and stress history information, used to identify areas that have previously experienced stress concentration or have been repaired, thereby better judging whether these areas have recurring hidden dangers.

Dam hidden danger types include, but are not limited to, stress concentration, water flow scour, cracks caused by thermal stress, and foundation instability.

Stress concentration hidden danger: the finite element analysis model is used to simulate the stress and deformation distribution of the dam under different load conditions. The geometric information and material property data provided by the BIM model are discretized into multiple structural units, and the stress changes of these units under static loads (such as water pressure) and dynamic loads (such as earthquakes or floods) are calculated. Through stress tensor and deformation calculations, stress concentration areas are identified. These areas are often weak points of the structure and may lead to cracks, deformation, or even failure. For example, when a certain part of the dam bears excessive pressure or stress, the finite element analysis model can identify this location and, combined with the historical records of the BIM model, determine if it is outside the safety threshold.

Water flow scour hidden danger: the fluid dynamics model combined with the BIM model is used to analyze the dynamic impact of water flow on the dam. The fluid dynamics model, based on the dam body outline and boundary conditions provided by the BIM model, simulates the interaction between water flow and the dam structure, predicting areas that may suffer structural damage due to excessive water pressure or water flow scour. The structural geometric information provided by the BIM model provides accurate boundary conditions for fluid dynamics analysis, enabling the fluid dynamics model to simulate real water flow behavior, thus more accurately identifying water pressure-sensitive areas.

Temperature change hidden danger: the heat conduction model simulates the thermal stress distribution of the dam under different temperature conditions. Combined with the material properties and structural location provided by the BIM model, it identifies material expansion or contraction caused by temperature changes. Under extreme temperature conditions (such as very cold or very hot climates), dam materials will generate thermal stress, leading to cracks or deformation. By simulating and analyzing the stress distribution caused by temperature changes, the system can identify affected parts and judge their stability.

Foundation instability hidden danger: the soil mechanics model evaluates the stability of the dam foundation by analyzing the interaction between the dam and the foundation soil. The foundation data provided by the BIM model is combined with the soil mechanics model to evaluate the bearing capacity and sliding risk of the foundation. By analyzing structural instability that may be caused by foundation settlement or slippage, potential hazards of the dam foundation are identified, especially areas where settlement, landslides, or collapse may occur, thereby ensuring the safety of the dam foundation. A common soil model is the Mohr-Coulomb model, which can evaluate the support effect of the soil on the dam and analyze the stability of the soil under extreme conditions.

4.3) Hazard marking: mark the hazards analyzed by the aforementioned models on the BIM model and determine the specific location of the hazards within the dam structure.

The BIM model not only provides geometric and material information but also helps precisely locate the hazard position through its 3D visualization function.

Hazard marking: when mathematical, physical models, and their hybrid models identify potential hazards, these hazards are marked on the corresponding structural units of the BIM model. For example, when finite element analysis identifies a stress concentration area, that area is highlighted with color on the BIM model, which can be used for quick identification of the hazard location.

Hazard location positioning: determine the specific location of the hazard within the dam structure through the 3D BIM model. The 3D BIM model can view different areas of the dam from multiple perspectives to understand the spatial distribution of hazards. Ensure accurate positioning of the hazard location for convenient on-site repair and handling.

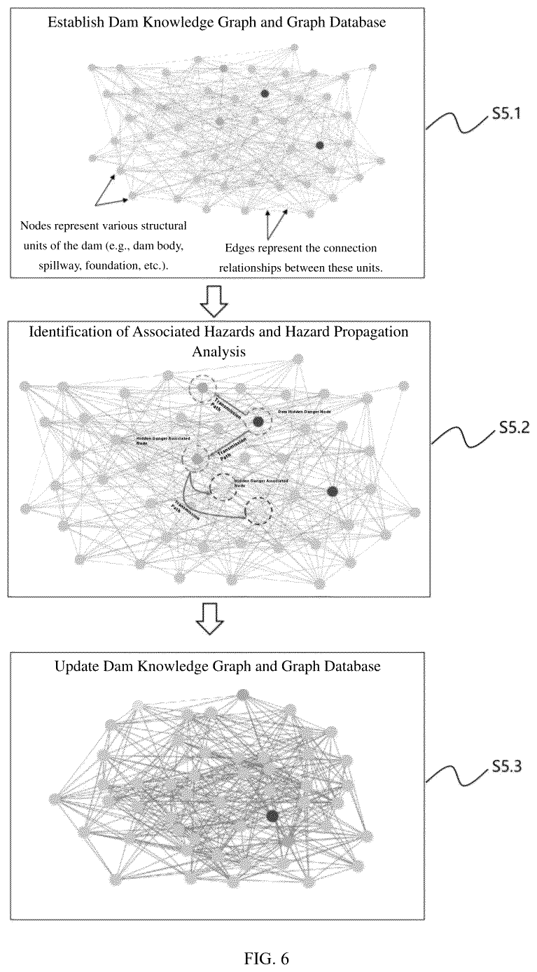

5) Based on historical dam data and real-time monitoring data, identifying associated hidden dangers to track the propagation path of hidden dangers within the dam, implemented by Module 5. As shown in FIG. 6, the dam hidden danger propagation path analysis flowchart, specific technical details and implementation methods are as follows:

5.1) Constructing the dam knowledge graph and graph database.

Abstracting the dam structure as a graph G=(V,E), where V is the set of nodes, representing various structural units of the dam. Structural units include the dam body, spillway, foundation, etc. E is the set of edges, representing the connection relationships between structural units. Nodes contain attribute information of the corresponding structure. Attribute information includes historical detection data, material strength, stress distribution, etc. The attribute of node ν is represented as a vector: A(ν)=[Historical detection data, Material strength, Stress distribution]. Edges contain physical connections of the structure and related attribute information. The attribute of edge e_{νj} connecting node ν and node j is represented as: W(e_{νj})=[Material strength, Force transmission relationship]. The hidden danger propagation relationship is a dynamic attribute, closely related to the state of the node (such as the probability of a hidden danger occurring) and the propagation weight of the edge (such as hidden danger influence probability, hidden danger propagation intensity). This type of information usually needs to be dynamically generated through real-time calculation or historical data analysis, rather than being a fixed static attribute of the edge. Therefore, only static attributes (material strength and force transmission relationship) are listed in the initial definition. In this embodiment, the main purpose of constructing edge attributes is to describe the physical and mechanical relationships between structural units to support basic structural analysis (such as stress transmission). The complexity of hidden danger propagation relationships is high and may be divided into a separate calculation module, not as a default static attribute of the edge.

Storing the node set and edge set in a graph database. Efficiently managing structural data through the graph database and provide basic materials for subsequent hidden danger propagation analysis. This structured data storage method makes data query and analysis more efficient, providing accurate information in a short time. The graph database contains the node set, edge set, and also contains the node connectivity used to represent the degree of association between a structural unit and other structural units.

The role of node connectivity LJ(ν) is to measure the relative importance of node ν in the dam structure, specifically reflecting the degree of connection between this node and other structural units. By calculating the connectivity of nodes, their position and role in the overall dam structure can be judged. If the connectivity of a node is high, it means it is connected to multiple other nodes, indicating that this node may undertake important functions or bear greater stress in the structure. The connectivity LJ(ν) of node ν can be expressed as:

$$LJ ( v ) = {\sum }_{j = 1}^{n} {A}_{jv}$$

where A_{jν} is an element in the adjacency matrix, indicating whether node j is connected to node ν, and n is the total number of nodes in the knowledge graph.

The adjacency matrix is a matrix used to represent the graph structure, which can clearly display the connection relationships between nodes. If the connectivity of a certain node is high, it means that the node is in a key position in the dam structure and may have a greater impact on the overall safety of the dam.

The Pagerank algorithm is used to evaluate the relative importance of each node in the dam. The calculation formula is:

$$PR ( v ) = \frac{1 - d}{n} + d {\sum }_{u ∈ {B}_{v}} \frac{PR ( u )}{L ( u )}$$

where PR(ν) is the relative importance score of node ν, B_{ν} is the set of nodes connected to node ν, L(u) is the number of outgoing edges of node u, d is the damping factor (usually set around 0.85), and n is the total number of nodes. This score can help the system identify key nodes in the dam structure, especially when the dam is under stress or has hidden dangers, these key nodes may be the parts that need the most attention.

5.2) Identification of associated hidden dangers and hidden danger propagation analysis. Identifying possible associated hidden dangers near the hazard location determined in step 4. The core of the knowledge graph is indeed composed of nodes and edges. Nodes represent entities (such as structural units of the dam, hidden dangers, etc.), and edges represent relationships between nodes (such as connection, influence, etc.). However, the richness and functionality of the knowledge graph are not only reflected in the connection of nodes and edges but also include the attribute information related to nodes and edges.

Node attributes: each node can carry rich attribute information, such as historical detection data, material strength, stress distribution, etc. These attributes provide important background for understanding the characteristics and state of the node. For example, the material strength and historical detection data of a certain structural unit of the dam can help assess the safety of that unit.

Edge attributes: the attributes of edges describe the characteristics of the relationship between nodes, such as force transmission relationship or connection strength. These attributes help analyze the mutual influence between different structural units, especially when a hidden danger occurs, understanding how force is transmitted within the structure is crucial.

Information integration: the knowledge graph can integrate information from different sources, such as historical hidden danger records, maintenance logs, and expert suggestions. This information can serve as a supplement to nodes and edges, helping to build a more comprehensive hidden danger network. For example, the location of a certain hidden danger may be related to a specific state of a node in the historical records. This relationship can be described by edges in the knowledge graph.

Hidden danger propagation analysis: by analyzing nodes and their attributes and the characteristics of edges, the knowledge graph can identify associations between hidden dangers and track the propagation path of hidden dangers within the dam. This propagation analysis not only relies on the connectivity of nodes and edges but also comprehensively considers attribute information to more accurately assess the impact of hidden dangers on the entire structure.

Therefore, the value of the knowledge graph lies in its ability to provide deep understanding and analysis capabilities of complex structures through rich node and edge attribute information, thereby effectively supporting hidden danger identification and propagation analysis.

To analyze hidden danger propagation, the system constructs a hidden danger influence matrix. The hidden danger influence matrix is a structured data table used to represent the hidden danger correlation between different structural units of the dam. In this matrix, rows and columns represent each node, and the value of each cell reflects the strength or risk degree of hidden danger propagation between two nodes. These values can be calculated based on historical hidden danger records, node material strength, stress distribution, and other factors. By analyzing the hidden danger influence matrix, managers can identify high-risk nodes and formulate timely prevention and repair measures accordingly, thereby effectively reducing potential risks and ensuring the safe operation of the dam. By analyzing this matrix, managers can identify high-risk nodes and take timely measures.

Performing shortest path calculation based on the graph database, used to analyze the propagation path of hidden dangers within the dam structure. The formula for calculating the shortest path is:

$$d ( u , v ) = min {\sum }_{i = 1}^{k} w ( {e}_{i} )$$

where d(u, ν) represents the shortest path distance between node u and node ν, w is the weight of edge e; on the path, and k is the number of edges on the path. In dam monitoring, the weight setting of edges is determined based on multiple key factors. Firstly, physical distance is an important consideration. The shorter the distance between connected nodes, the lower the weight of the edge is usually set, because the possibility of hidden danger propagation over a short distance is higher. Furthermore, the strength of force transmission also affects the weight. The higher the strength and stiffness of the connecting material, the greater the resistance to hidden danger propagation, and the corresponding weight can be lower. Historical hidden danger data is also important. If a certain path frequently experienced hidden danger propagation in the past, the weight of the edge should be adjusted lower to reflect higher risk. Environmental factors such as rainfall, temperature changes, and material properties also affect weight setting. By comprehensively considering these factors, reasonable weights can be set for each edge, making the shortest path calculation more accurate and ensuring the scientificity and effectiveness of hidden danger propagation analysis. Calculate the possibility and speed of hidden danger propagation from one node to other nodes through the shortest path algorithm.

Furthermore, the graph database also supports complex path traversal queries. It can efficiently traverse relevant paths in the dam structure according to user-set conditions and provide detailed information on the path (such as the state of each node, edge attributes). Path traversal query methods include using recursive traversal algorithms to query all paths P(u,ν) between node ν and node u, and evaluate the importance of the path based on the edge weights w and node states on the path. In hidden danger propagation analysis, node state refers to the health or safety status of each node at a specific time, reflecting its current safety and potential risk. Node state usually includes safety levels, such as “safe”, “warning”, or “danger”, which are evaluated through real-time monitoring data (such as stress, displacement, and temperature). Furthermore, if a node has been identified as having a hidden danger, its state will include the type of hidden danger, severity, and possible impact range. Historical monitoring records and maintenance logs also affect the node state, especially nodes that have had hidden dangers before require more attention. Environmental factors, such as rainfall or earthquakes, also affect the node state, causing changes in its safety. By comprehensively evaluating the node state, the system can effectively predict the risk of hidden danger propagation and provide important basis for management decisions.

If a hidden danger occurs at a certain node, the system will calculate the impact of this hidden danger on its adjacent nodes and predict the range that the hidden danger may affect through a propagation model. The hidden danger propagation probability can be expressed by the following formula:

$$F ( u , v ) = P ( u ) \cdot exp ( - \frac{d ( u , v )}{{d}_{0}} )$$

where F(u, ν) is the probability of hidden danger propagating from node u to node ν, P(u) is the probability of hidden danger occurring at node u, d(u, ν) is the shortest path distance between node u and node ν, and d₀ is the influence radius set by the system. This formula indicates that the possibility of hidden danger propagation decays as the distance between nodes increases. Based on the propagation prediction results, the system can trigger a warning mechanism. Especially when key nodes are threatened, the system will automatically issue a warning, prompting dam managers to conduct further detection or take preventive measures.

Obtaining the probability P(u) of a hidden danger occurring at a node can be achieved through various methods. Firstly, historical data analysis is an effective approach. By counting the frequency of hidden dangers occurring at that node in the past and the ratio to the total number of monitoring times, the probability can be estimated. Furthermore, real-time monitoring data can also provide important information. Using sensor-monitored data such as stress, displacement, and temperature, combined with set safety thresholds, the health status of the node is assessed, thereby determining the possibility of a hidden danger occurring. Constructing statistical models is also a common method, predicting the probability of hidden dangers through various influencing factors (such as material properties, environmental conditions, etc.). Finally, expert evaluation can provide basis for the probability, combining professional knowledge to conduct in-depth analysis of node characteristics. Through these methods, the system can dynamically update the probability of hidden danger occurrence at nodes, providing accurate support for hidden danger propagation prediction.

5.3) Updating the dam knowledge graph and graph database. The data of nodes and edges in the knowledge graph and graph database are continuously incrementally updated as monitoring data is updated, implemented by an incremental update algorithm.

Updating the state information of nodes based on real-time sensor data, including structural health status, stress situation, etc. Meanwhile, the attributes of edges are also dynamically adjusted. For example, if abnormalities in force transmission are found in certain areas during structural inspection, adjust the corresponding weights and recalculate the shortest path and node importance.

By introducing an incremental update algorithm, only the parts of nodes and edges that have changed are updated, greatly improving the response speed and operational efficiency of the system.

6) Pre-training and fine-tuning of the multi-modal large model, implemented by Module 6. Pre-train and fine-tune the multi-modal large model to enable it to learn to obtain risk assessment results, warning thresholds, and warning response mechanisms based on the real-time monitoring data, external resource data, historical dam data, hidden danger locations and types, and dam hidden danger propagation paths. As shown in FIG. 7, the technical details and implementation methods of pre-training and fine-tuning the multi-modal large model are as follows:

6.1) dataset construction and preprocessing.

Dataset construction: collecting historical multi-modal monitoring data (from Module 1), external resource data (from Module 2), historical dam data (from Module 3), hidden danger locations and types (from Module 4), hidden danger propagation paths (from Module 5). Forming input samples based on the above data: sensor data deployed on the dam, historical hidden danger records, engineering technical documents formed during various stages of dam planning, design, construction, and operation, dam safety-related information resources, geometric and material information of the BIM model, timestamp and spatial location information.

Data preprocessing: including data cleaning (removing invalid data generated by sensor failures, noise, and outliers), format unification (such as equal-interval processing of time series data, vectorization of text data through word segmentation and keyword extraction), alignment and synchronization (achieving time synchronization of multi-modal data based on timestamps, and aligning sensor data with the BIM model through unified spatial coordinates), and normalization processing (using Min-Max Scaling for continuous data, one-hot encoding for categorical data).

Data labeling: creating labels for each sample, including a binary label indicating whether a hidden danger event occurred (0: not occurred, 1: occurred), the probability value of the hidden danger event occurring (calculated by the ratio of the number of times a hidden danger occurred under specific conditions to the number of times those conditions appeared), and the type and impact degree of the hidden danger event as auxiliary labels for the event classification task. The calculation data for data labels originates from historical dam data (from Module 3), hidden danger locations and types (from Module 4), and hidden danger propagation paths (from Module 5).

Data augmentation: in cases of insufficient or imbalanced data, data augmentation techniques can be used to improve the model's generalization ability. This includes cutting long time series into short time windows to extract more features, jointly sampling multi-modal data to generate new samples, and using simulation methods to generate synthetic samples of sensor data or hidden danger propagation paths, thereby enriching the diversity and completeness of the dataset.

Modal feature encoding: the Transformer model requires serialized vectorized feature input. For this purpose, multi-modal data is feature encoded: sensor data uses sliding windows to extract time series features, visual data extracts image features through pre-trained CNNs (such as ResNet or ViT), text data uses pre-trained language models (such as BERT) to generate embedding vectors, BIM model data extracts geometric and material properties and numericalizes them, spatiotemporal information encodes timestamps and spatial locations into numerical vectors. These features are processed separately by independent encoders, providing a foundation for the fusion of multi-modal features for the model.

Data organized into Transformer input format: the Transformer architecture requires organizing multi-modal features into sequence form. Each sample constitutes a sequence, where each element corresponds to a feature vector of a modality (e.g., modality 1 feature, modality 2 feature, modality 3 feature, . . . modality 1 feature, modality 2 feature, modality 3 feature, . . . modality 1 feature, modality 2 feature, modality 3 feature, . . . ). The multi-head self-attention mechanism of the Transformer is used to achieve the fusion of modal features, generating a joint representation with context correlation, providing a foundation for comprehensive analysis of multi-modal data.

Saving the training set: to facilitate efficient training and validation of the model, the training set needs to be saved in a format suitable for batch loading (such as .csv, .json, or .tfrecord) and divided according to certain rules. Usually, methods like chronological order or random ratio are used to divide the data into training set and validation set, for example, 80% of the data for training and 20% for validation, thus ensuring the scientificity and accuracy of model training and evaluation.

6.2) Model pre-training and fine-tuning.

Based on the dataset established above, the multi-modal large model fuses the features of each modality through the multi-head self-attention mechanism of the Transformer. These data from different sources are aggregated into the Transformer model for joint analysis, enabling the model to provide information support from multiple dimensions when capturing hidden dangers. Through the joint processing of multi-modal data, the system can comprehensively assess the health status of the dam based on abnormal audio signals combined with surface change information in images.

The loss function for pre-training the deep learning model based on the Transformer architecture is as follows:

$$L ( θ ) = - \frac{1}{N} {\sum }_{i = 1}^{N} [ {y}_{i} log ( {\hat{y}}_{i} ) + ( 1 - {y}_{i} ) log ( 1 - {\hat{y}}_{i} ) ]$$

where yᵢ is the actual label, ŷᵢ is the model's prediction result, N is the total number of samples, and θ is the model parameter. This loss function is used to evaluate the difference between the model's prediction result and the actual result.

To reduce the loss value of the model and optimize the model parameters, the gradient descent algorithm is introduced. The formula is as follows:

$${θ}_{new} = {θ}_{old} - η {∇}_{θ} L ( θ )$$

where η is the learning rate, and η∇_{θ}L(θ) is the gradient of the loss function with respect to the parameters. By continuously updating the model's parameters, the model is gradually optimized to enable it to process and analyze dam monitoring data more accurately.

To prevent the model from overfitting during the training process, L2 regularization technology is introduced to maintain the model's generalization ability, so that even when facing unseen data, the model can make accurate predictions. The formula is as follows:

$${L}_{reg} ( θ ) = L ( θ ) + λ {\sum }_{i = 1}^{n} {θ}_{i}^{2}$$

where λ is the regularization parameter, used to control the complexity of the model and prevent the model from over-relying on the training data.

6.3) Continuous learning and optimization of the model: through online learning mode, use new monitoring data to continuously update the model, maintaining its sensitivity to environmental changes.

The key to online learning is quick response to new data and dynamic adjustment of model weights. For example, during floods or extreme weather events, use the latest monitoring data to quickly update model parameters, enhancing the model's ability to respond to emergencies. Meanwhile, the system's closed-loop feedback mechanism allows comparing each prediction result with actual data, obtaining errors from it, and adjusting the model, keeping it stable and high-performing during long-term monitoring.

In the process of continuous learning and optimization of the model, error refers to the difference between the model's prediction result and the actual observed value. This difference can be quantified in various ways. For example, prediction error is the deviation between the model's output for input data and the true label. The loss function is used to comprehensively evaluate this error, such as commonly used loss functions like mean squared error and cross-entropy. In online learning, the system uses a closed-loop feedback mechanism to compare each model prediction result with the latest monitoring data, calculating the feedback error. This process not only helps the model adjust weights and parameters but can also decompose the error into bias and variance, further optimizing model performance. Through continuous monitoring and analysis of errors, the system can improve its ability to respond to emergencies in real time, ensuring the provision of scientific and effective decision support for dam safety management.

Through continuous optimization, continuously adjust model weights and parameters based on the latest data, ensuring that under various complex environments, it can always provide scientific and effective decision support for dam safety management.

7) Comprehensive dam safety warning and response based on the multi-modal large model: inputting real-time monitoring data, the type and location of hidden dangers, historical dam data related to the hidden dangers, the propagation path of hidden dangers within the dam, and external resource data related to the hidden dangers into the pre-trained multi-modal large model. Analyzing based on historical dam data and real-time external resource data to obtain the probability of dam hidden danger occurrence, the impact degree of hidden dangers, and warning thresholds, thereby outputting risk assessment results and warning response mechanisms, implemented by Module 7.

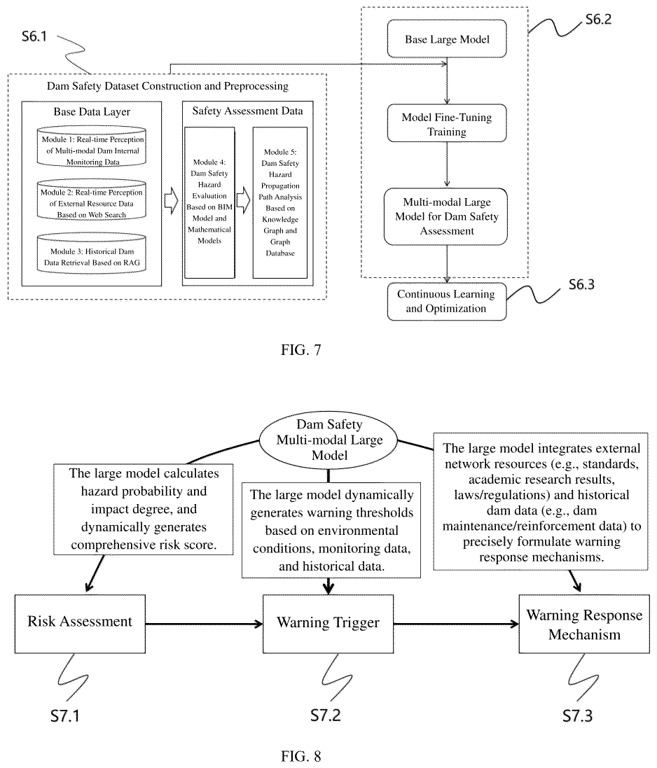

As shown in FIG. 8, the comprehensive dam safety warning and response mechanism based on the multi-modal large model, specific technical details and implementation methods are as follows:

7.1) the multi-modal large model integrates real-time monitoring data, external resource data, and historical data to predict the probability of dam hidden danger occurrence P_{failure} and the potential impact degree C_{impact} that dam hidden dangers may bring, thereby generating final risk assessment results.

(1) Hidden danger occurrence probability P_{failure}: the multi-modal large model uses real-time monitoring data from multi-modal sensors, including water flow pressure, vibration, temperature, displacement, and other information, to analyze the current structural state of the dam.

These data reflect the operating status of the dam under different environmental conditions and provide rich feature vectors for the multi-modal large model. Through deep learning algorithms, the multi-modal large model can identify potential hidden dangers and calculate their occurrence probability P_{failure}. In addition to internal sensor real-time monitoring data, the multi-modal large model also fully utilizes external resource data and historical dam data to improve prediction accuracy. Through comprehensive analysis of these multi-dimensional data, the multi-modal large model can more accurately judge the probability of hidden dangers caused by dam maintenance records and other factors, and dynamically adjust the value of P_{failure}.

External resource data obtained through web search provides cutting-edge references for the risk prediction of the multi-modal large model. For example, accident case analysis worldwide can help the multi-modal large model identify hidden danger scenarios similar to the current condition of the dam, thereby more precisely adjusting P_{failure}.

Historical dam data comes from the dam basic data knowledge base constructed by RAG (Retrieval-Augmented Generation). By analyzing historical records, the multi-modal large model can capture the long-term operation trends, maintenance history, and hidden danger distribution of the dam, and combine these data to predict the current probability of hidden danger occurrence. For example, if historical records show that hidden dangers have occurred multiple times in certain areas, the multi-modal large model can increase the hidden danger occurrence probability P_{failure} value for these areas.

(2) Impact degree C_{impact}: the multi-modal large model evaluates the potential impact degree C_{impact} that dam hidden dangers may produce, assessing the potential consequences of risks. The impact degree C_{impact} depends not only on the probability of hidden danger occurrence but also on the degree of threat this hidden danger poses to key parts of the dam. The multi-modal large model calculates the damage that each type of hidden danger may cause through the analysis of historical hidden danger records and dam maintenance data. The calculation formula for C_{impact} is:

$${C}_{impact} = {\sum }_{i = 1}^{n} ( {I}_{i} \times {P}_{failure}^{i} )$$

where Iᵢ represents the impact degree of the i-th type of hidden danger event on the dam,

$${P}_{failure}^{i}$$

is the occurrence probability of that type of hidden danger event, and n represents the number of hidden danger event types. This formula integrates the risk levels of multiple hidden dangers and assigns different weights to each hidden danger. The model derives a comprehensive impact degree value based on factors such as the structural damage, economic loss, and ecological impact that these hidden dangers may bring. By quantifying the impact of various hidden dangers, managers can prepare for prevention and response in advance.

(3) Comprehensive risk score R: obtaining the comprehensive risk score R by combining the hidden danger occurrence probability P_{failure} and the impact degree C_{impact}:

$$R = α {P}_{failure} + β {C}_{impact}$$

where α_{P} is the weight of the hidden danger occurrence probability P_{failure}, and β_{C} is the weight of the impact degree C_{impact}. The weights α_{P} and β_{C} can be obtained through various methods. Firstly, expert experience and industry standards can be used to initially set the weight values, ensuring their reasonableness. Secondly, collect user feedback and managers' opinions to understand the importance of hidden danger occurrence probability and impact degree to decision-making in actual operations, and make corresponding adjustments. Furthermore, through A/B testing, different weight combinations can be used in different scenarios to compare effects and find the optimal configuration. Using machine learning models is also an effective method. By training the model to automatically learn weights, it can better align with actual needs. Finally, statistical analysis of historical data can help evaluate the changing trends of hidden danger occurrence probability and impact degree, thus providing data support for weight setting. Through these methods, the comprehensive risk score will be more accurate and can provide effective decision-making basis for dam safety management.

The output of the multi-modal large model directly affects the final value of the comprehensive risk score, thereby providing data support for dam risk management. In this way, managers can more comprehensively understand potential risks and formulate reasonable risk response strategies accordingly. For example, when the R value is high, the system may suggest increasing monitoring frequency, strengthening dam maintenance work, or preparing emergency measures.

The multi-modal large model analyzes multi-modal data to calculate the probability of hidden danger occurrence and the impact degree, providing accurate and intelligent support for dam safety risk assessment. The comprehensive risk score generated by the system not only helps identify potential hidden dangers but also provides scientific basis for dam managers, ensuring timely and reasonable risk response strategies.

7.2) Dam safety risk warning trigger. The multi-modal large model dynamically adjusts warning thresholds through comprehensive analysis of internal sensor data, external resource data, and historical data. The specific adjustment mechanism is as follows:

(1) threshold adjustment based on model output: when the multi-modal large model predicts that the occurrence probability P_{failure} of a certain type of hidden danger exceeds the set threshold (e.g., 70%), the system proactively lowers the alarm threshold of sensors associated with that hidden danger to increase monitoring sensitivity. The reduction amplitude is determined based on the extent to which the hidden danger occurrence probability exceeds the set threshold. For example, for every 5% the hidden danger occurrence probability exceeds the threshold, the alarm threshold of related sensors is reduced by 2% to 5%. Specifically, when the hidden danger occurrence probability is high, the threshold is lowered; when the hidden danger occurrence probability is low and the external environment is stable, the threshold can be appropriately increased to reduce false alarms. For example, if the model predicts that the probability of structural stress hidden danger in a certain area reaches 80%, exceeding the set threshold by 10%, the system reduces the alarm threshold of stress sensors in that area by 5% to 10% to more sensitively capture stress changes.

(2) Threshold adjustment in response to external environmental data: when external environmental forecasts (such as heavy rain, earthquakes, etc.) indicate possible impacts on the dam, the system dynamically adjusts the alarm thresholds of related sensors based on the degree of environmental impact. In case of expected heavy rain, the system lowers the alarm thresholds of seepage sensors and water level sensors. The reduction amplitude can be adjusted according to the rainfall level (moderate rain, heavy rain, storm), for example, reduced by 5% to 15%. In case of earthquake warning, the system adjusts the alarm thresholds of ground stress and vibration sensors based on the earthquake magnitude and the distance from the epicenter to the dam. The larger the magnitude and the closer the distance, the greater the reduction amplitude, possibly reduced by 10% to 20%. By lowering thresholds, the sensitivity of sensors to abnormalities caused by external environmental changes is increased, ensuring potential risks can be detected in time.

(3) Threshold optimization based on historical data: the system regularly analyzes the deviation between sensor data and historical hidden danger records and dynamically adjusts warning thresholds. When the data of a certain sensor triggers alarms multiple times under conditions 5% to 10% higher than the set threshold, the system determines that the current threshold may be too sensitive or insensitive. Adjust the threshold appropriately increase or decrease according to the degree of deviation, with an adjustment amplitude generally between 5% and 10%. For example, if historical data indicates that the occurrence rate of a certain type of hidden danger increases under specific environmental conditions (such as sustained high temperature, the system will lower the threshold of related sensors during this period to increase monitoring sensitivity.

(4) Threshold anomaly detection and adaptive optimization: the system dynamically adjusts warning thresholds by monitoring changes in sensor data in real time and using anomaly detection algorithms. When sensor data shows abnormal fluctuations (such as drastic changes in a short time) and does not conform to historical trends, the system identifies it as an anomaly. If the anomaly persists beyond the preset time (e.g., 30 minutes), the system combines historical data and external information to appropriately adjust the threshold, with an adjustment amplitude of 5% to 10%. When data abnormalities are caused by equipment aging or external interference, adjust the threshold to avoid false alarms or missed alarms.

(5) Comprehensive evaluation and threshold adjustment: the system comprehensively considers the hidden danger occurrence probability output by the model, external environmental changes, and historical data to determine the direction and amplitude of threshold adjustment. In high-risk scenarios, when the hidden danger occurrence probability is high and the external environment is unfavorable, the threshold is lowered, with an amplitude of up to 20%, and the monitoring frequency is increased. In low-risk scenarios, when the hidden danger occurrence probability is low and the environment is stable, the threshold can be appropriately increased by 5% to 10% to reduce false alarms and improve system efficiency. The threshold adjustment is directly based on the hidden danger occurrence probability output by the model. The higher the probability, the more the threshold is lowered, and the more sensitive the monitoring system becomes. This dynamic adjustment mechanism ensures the precision and flexibility of the warning system.

7.3) Dam safety risk warning response mechanism: the dam safety risk warning response mechanism is a key system to ensure that managers can quickly take effective countermeasures when the dam faces potential risks. This mechanism relies on the output of the multi-modal large model, combined with external resource data and historical dam data, to provide accurate and dynamic warning response strategies for dam management. Through the web search function to obtain the latest global standards and specifications, academic papers and laws and regulations, and the dam basic data knowledge base constructed based on RAG technology, the system can establish a sound warning response mechanism, ensuring the scientificity and timeliness of decisions.

The multi-modal large model ensures that dam monitoring and emergency strategies comply with international standards by retrieving the latest technical standards and specifications through Module 2. For example, updates on flood and earthquake emergency response and monitoring equipment installation requirements will be promptly incorporated into the warning mechanism, helping managers adjust emergency measures according to these standards, ensuring their compliance and scientificity. Academic research provides the latest results for dam risk assessment, structural reinforcement, etc., supporting managers in more scientifically formulating protection plans and improving the effectiveness of emergency measures. Furthermore, the system can obtain the latest laws and regulations, ensuring that dam managers comply with relevant laws in disaster warning, evacuation, and other emergency responses, avoiding legal risks.

The multi-modal large model identifies high-risk areas based on historical maintenance and reinforcement records and prioritizes monitoring these weak parts during emergencies. Hidden danger logs and operation logs help the system analyze past hidden dangers and their handling methods, thus providing countermeasures for warning response. For example, if certain areas have experienced hidden dangers under similar environmental conditions before, the multi-modal large model will propose corresponding emergency plans based on historical data, such as increasing monitoring frequency or implementing preventive reinforcement, ensuring that managers can quickly make targeted responses to reduce potential losses.

By combining external resource data obtained through the web search function and historical dam data provided by the RAG knowledge base, the multi-modal large model ultimately forms a comprehensive risk warning response mechanism. The system can provide precise warning signals when the dam faces risks, and combined with standards and specifications, academic research, laws and regulations, and historical maintenance and reinforcement data, provide comprehensive emergency decision support for managers.

This mechanism ensures that managers can not only formulate emergency plans based on the latest standards, specifications, and laws and regulations but also identify high-risk areas and hidden danger propagation paths based on the historical operation data of the dam, precisely formulating protection strategies. In emergency states, the system can dynamically adjust response plans based on real-time analysis of multi-source data, ensuring the scientificity, timeliness, and compliance of emergency measures, effectively guaranteeing the safety and reliability of the dam.

The contents not described in detail in this specification belong to the prior art known to those skilled in the art.

1. A multi-modal large model construction and operation method for reservoir dam safety, including the following steps:
constructing a training set: collecting historical multi-modal monitoring data, external resource data, historical dam data, hidden danger locations and types, hidden danger propagation paths, forming input samples based on said data; calculation data for training labels originates from historical dam data, hidden danger locations and types, and hidden danger propagation paths;
the process of obtaining the hidden danger propagation path includes: defining each structural unit of the dam as a structural unit node and assigning attributes; defining physical connections and mechanical relationships between structural units as structural connection edges and assigning attributes;
establishing association relationships between nodes and edges: establishing edges between structural unit nodes based on historical operational state data, engineering technical documents, and geometric information from the BIM model;
storing node and edge information in a graph database; performing calculations on the nodes and edges in the graph database to obtain node connectivity and importance scores;
updating the health status and risk level of nodes in the knowledge graph, as well as the weights and influence probability of edges, based on real-time collected dam operational state data and new external information resources;
analyzing the path and probability of a hidden danger propagating from one structural unit to another using the updated node and edge attributes and the results of connectivity calculations;
based on the hidden danger propagation probability, constructing a matrix representing the hidden danger correlation between nodes; calculating the shortest path of hidden danger propagation from a source node to other nodes by combining the hidden danger influence matrix and the graph database; identifying nodes that have significant influence in the hidden danger propagation process based on their importance score and role in the propagation process;
the individual samples in the training set include: as model input multi-modal data: sensor data deployed on the dam, historical hidden danger records, engineering technical documents formed during various stages of dam planning, design, construction, and operation, dam safety-related information resources, geometric and material information of the BIM model, timestamp and spatial location information; and as training labels, whether a hidden danger event occurred and the probability value of the hidden danger event occurring;
training a multi-modal prediction model based on the Transformer architecture using the training set;
performing real-time prediction and early warning for dam safety hazards using the trained model, based on real-time collected monitoring data, the type and location of hidden dangers, historical dam data related to the hidden dangers, the propagation path of hidden dangers within the dam, and external resource data related to the hidden dangers;
calculating the actual impact degree of the hidden danger event, a comprehensive risk score, warning thresholds for sensors associated with the hidden danger event, and emergency measure suggestions based on the probability value of whether the hidden danger event occurred output by the model.

2. The multi-modal large model construction and operation method for reservoir dam safety of claim 1, wherein the data is preprocessed before being used to construct the training set: cleaning the collected raw training sample data to remove abnormal data and invalid data; labeling the data in a unified format and organizing into structured data suitable for model training; time alignment of image and vibration data is achieved through timestamps, and performing unified processing of spatial coordinates.

3. The multi-modal large model construction and operation method for reservoir dam safety of claim 1, wherein the sensors deployed on the dam include, but are not limited to: physical quantity sensors, vibration sensors, visual sensor data, audio sensors, and environmental sensors.

4. The multi-modal large model construction and operation method for reservoir dam safety of claim 1, wherein during the model training process, a binary cross-entropy loss function, gradient descent algorithm, and L2 regularization are used to optimize model parameters.

5. The multi-modal large model construction and operation method for reservoir dam safety of claim 1, wherein before training and using the multi-modal prediction model based on the Transformer architecture, the data of each input modality is preprocessed through independent encoders, and the features of each modality are fused through the multi-head self-attention mechanism of the Transformer and then used as model input.

6. The multi-modal large model construction and operation method for reservoir dam safety of claim 1, wherein the actual impact degree of the hidden danger event C_{impact} is calculated using the following formula:
$${C}_{impact} = {\sum }_{i = 1}^{n} ( {I}_{i} = {P}_{failure}^{i} )$$
where Iᵢ represents the impact degree of the i-th type of hidden danger event on the dam,
$${P}_{failure}^{i}$$
is the occurrence probability of that type of hidden danger event, and n represents the number of hidden danger event types.

7. The multi-modal large model construction and operation method for reservoir dam safety of claim 6, wherein the comprehensive risk score R is calculated using the following formula:
$$R = α {P}_{failure} + β {C}_{impact}$$
where α is the weight of the hidden danger occurrence probability, representing its relative importance in risk assessment, and β is the weight of the hidden danger impact degree, representing its contribution to the comprehensive score.

8. The multi-modal large model construction and operation method for reservoir dam safety of claim 3, wherein the warning threshold for sensors associated with the hidden danger event is comprehensively adjusted according to the following principles and their corresponding weights:
when the occurrence probability of any type of hidden danger is greater than its set upper limit threshold, adjusting the warning threshold of the sensor associated with that hidden danger according to the magnitude by which the probability exceeds its set upper limit threshold, to increase the sensitivity of said sensor; when the occurrence probability of any type of hidden danger is less than its set lower limit threshold, adjusting the warning threshold of the sensor associated with that hidden danger according to the magnitude by which the probability is below its set lower limit threshold, to decrease the sensitivity of said sensor;
when the input dam safety-related information resources include weather forecasts of a set type and severity, adjusting the warning threshold of the sensor associated with that weather forecast according to the weather forecast, to increase the sensitivity of said sensor;
adjusting the current warning threshold of a sensor based on the deviation between the sensor's historical warning threshold and historical hidden danger records;
adjusting the current warning threshold of a sensor based on abnormal fluctuations of the sensor.

9. The multi-modal large model construction and operation method for reservoir dam safety of claim 3, wherein the process of determining emergency measure suggestions includes: when the occurrence probability of any type of hidden danger is greater than its set upper limit threshold, obtaining corresponding emergency measure suggestions for that hidden danger based on the technical standards and specifications contained in the input dam safety-related information resources and the historical maintenance and reinforcement records for the corresponding hidden danger in the engineering technical documents.

10. A multi-modal large model construction and operation system for reservoir dam safety, comprising a training set construction module, a model training module, a prediction module, and an early warning module:
the training set construction module is used to construct the training set: the individual samples in the training set include: as model input multi-modal data: sensor data deployed on the dam, historical hidden danger records, engineering technical documents formed during various stages of dam planning, design, construction, and operation, dam safety-related information resources, geometric and material information of the BIM model, timestamp and spatial location information; and as training labels, whether a hidden danger event occurred and the probability value of the hidden danger event occurring;
the model training module is used to train a multi-modal prediction model based on the Transformer architecture using the training set;
the prediction module is used to perform real-time prediction and early warning for dam safety hazards using the trained model, based on real-time collected monitoring data;
the early warning module is used to calculate the actual impact degree of the hidden danger event, a comprehensive risk score, warning thresholds for sensors associated with the hidden danger event, and emergency measure suggestions based on the probability value of whether the hidden danger event occurred output by the model.
